(19) United States
(12) Patent Application Publication
(10) Pub. No.: US 2025/0079139 A1
(43) Pub. Date: Mar. 6, 2025

(54) IGNITION CONTROL METHOD AND SUBSTRATE PROCESSING APPARATUS

(71) Applicant: Tokyo Electron Limited, Tokyo (JP)

(72) Inventor: Takeshi KOBAYASHI, Iwate (JP)

(21) Appl. No.: 18/812,506

(22) Filed: Aug. 22, 2024

(30) Foreign Application Priority Data
Aug. 29, 2023 (JP) 2023-138513

(51) Int. Cl. H01J 37/32

(52) U.S. Cl. CPC H01J 37/32935; H01J 37/32183; H01J 37/32522; H01J 2237/24585; H01J 2237/332

(57) ABSTRACT

An ignition control method includes: providing a substrate processing apparatus including a pair of electrodes in a processing container, a matching box including a variable reactor and an electronic circuit, an RF power supply connected to the electrodes, and a temperature sensor that detects a temperature of the variable reactor; setting the temperature of the variable reactor to a first temperature, and measuring first information indicating a voltage between the electrodes for each adjustment position of the variable reactor when a radio-frequency voltage is applied to the electrodes; determining a preset value of the variable reactor based on the first information; acquiring the detected temperature of the variable reactor as a second temperature; and when the first and second temperatures are different, correcting the current by controlling the electronic circuit such that an adjustment position of the variable reactor becomes the determined preset value.

### CROSS-REFERENCE TO RELATED APPLICATIONS

This application is based on and claims priority from Japanese Patent Application No. 2023-138513, filed on Aug. 29, 2023, with the Japan Patent Office, the disclosure of which is incorporated herein in its entirety by reference.

### TECHNICAL FIELD

The present disclosure relates to an ignition control method and a substrate processing apparatus.

### BACKGROUND

In order to perform a stable plasma ignition, an adjustment position of a variable capacitor or a variable reactor provided in an impedance matching device is set to an appropriate position (e.g., set to a preset value) immediately before applying a radio-frequency voltage.

Japanese Patent Laid-Open Publication No. 2017-118434 discloses an electronic matcher capable of performing an impedance matching at high speed without requiring mechanical elements.

### SUMMARY

According to an aspect of the present disclosure, an ignition control method includes: (a) providing a substrate processing apparatus including a processing container that accommodates a substrate, a pair of electrodes disposed in the processing container, an impedance matcher including a variable reactor and an electronic circuit that controls a current flowing in the variable reactor, an RF power supply connected to the pair of electrodes via the impedance matching device, and a temperature sensor that detects a temperature of the variable reactor; (b) setting the temperature of the variable reactor to a first temperature, and measuring first information indicating a voltage between the pair of electrodes for each of a plurality of adjustment positions of the variable reactor when a radio-frequency voltage of a predetermined frequency is applied to the pair of electrodes from the RF power supply; (c) determining a preset value of the variable reactor based on the measured first information; (d) acquiring the temperature of the variable reactor detected by the temperature sensor as a second temperature; and (e) when the first temperature and the second temperature are different, correcting the current flowing in the variable reactor by controlling the electronic circuit such that an adjustment position of the variable reactor at the second temperature becomes the determined preset value.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a configuration of a substrate processing apparatus.

FIG. 2 is a view illustrating an example of a configuration of an impedance matching device and a plasma box according to an embodiment.

FIG. 3 is a view illustrating an overview of an operation of a variable reactor.

FIGS. 4A to 4D are views for describing a temperature change of the variable reactor and a problem arising at the time of plasma ignition.

FIG. 5 is a view illustrating a gas supply source, a control unit, and a controller of the substrate processing apparatus according to an embodiment.

FIG. 6 is a flowchart illustrating an ignition control method according to an embodiment.

FIG. 7 is a view illustrating an example of an inter-electrode voltage table at each adjustment position of the variable reactor.

FIG. 8 is a flowchart illustrating an example of a correction process of FIG. 6.

FIGS. 9A and 9B are each a view illustrating an example of a control current table of the variable reactor.

FIG. 10 is a flowchart illustrating an example of a film formation process of FIG. 6.

FIG. 11 is a time chart illustrating an example of the film formation process of FIG. 10.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, embodiments for implementing the present disclosure are described with reference to the drawings. In the drawings, the same component is denoted with the same reference numeral, and overlapping descriptions thereof are omitted.

### Overview

In a film formation using plasma, a high film quality and a high film formation speed are required. Further, various types of gases are used to generate plasma in a plasma processing using a plurality of gases as well as a plasma processing by a single gas.

As well-known by, for example, the Paschen's curve, minimum ignition voltages of the individual gases are different according to the different gases used. Thus, when different gases are used, the minimum ignition voltages required for plasma ignition are different. Therefore, stable plasma ignition that suppresses a reflected wave is required for each of the different gases. Further, in order to improve the quality of a formed film, it is necessary to respond the influence of temperature variation by plasma or a reaction product generated by film formation, and the influence of a periodic cleaning of the inside of a processing container for removing the reaction product.

In order to control the influences at high speed, a variable reactor is provided in an impedance matching device, and an impedance matching is performed by the impedance matching device using the variable reactor. When plasma is ignited, the impedance matching may be performed by setting an adjustment position of the variable reactor in the impedance matching device to an appropriate position (referred to as a preset value). However, the temperature of the variable reactor changes due to the environmental temperature or the operation of the device, and the appropriate preset value changes. Thus, the present embodiment provides an ignition control method and a substrate processing apparatus, which may implement stable plasma ignition by improving the accuracy of the preset value of the variable reactor according to the temperature of the variable reactor.

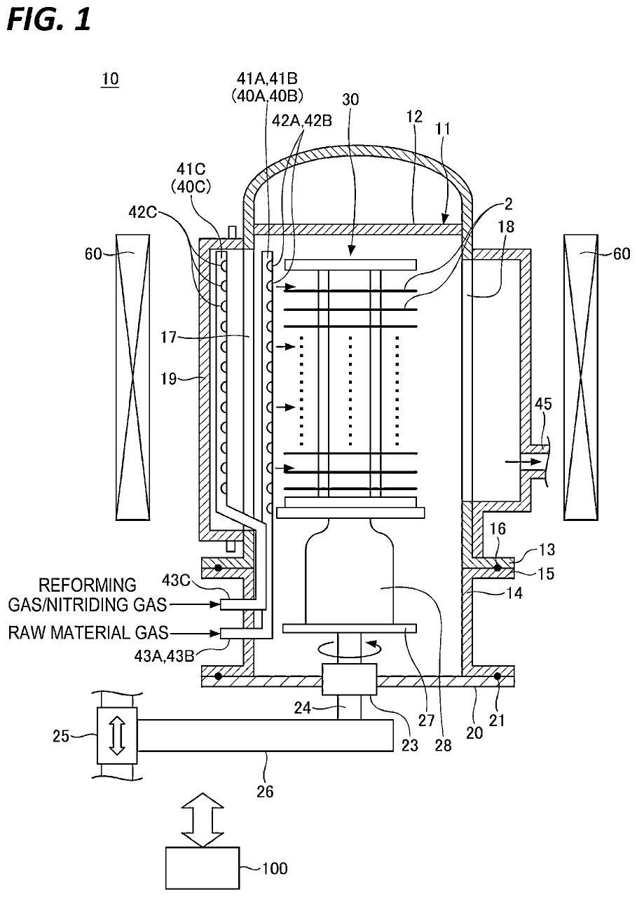

Hereinafter, the substrate processing apparatus, which performs the ignition control method according to the present embodiment, is described with reference to FIG. 1, and then, the ignition control method according to the present embodiment is described.

### Substrate Processing Apparatus

FIG. 1 is a view illustrating a substrate processing apparatus 10 according to an embodiment. The substrate processing apparatus 10 is an atomic layer deposition (ALD) apparatus that accommodates a plurality of wafers 2 in a processing container 11 and forms a predetermined film, such as nitride film, on the plurality of wafers 2, and is a batch-type vertical thermal processing apparatus that processes a plurality of wafers. The substrate processing apparatus 10 is an example of an apparatus that performs an ignition control method according to an embodiment to be described herein below.

In the substrate processing apparatus 10 according to the present embodiment, for example, silicon nitride film (SiN) is formed. However, the type of film to be formed is not limited thereto. The silicon nitride film is formed on the wafers 2 by alternately supplying a raw material gas (e.g., dichlorosilane gas) and plasma of nitriding gas (e.g., ammonia (NH₃) gas) onto the wafers 2. In this film formation method, the thickness of the nitride film formed within the plane of each wafer 2 tends to become thick at the edge of the wafer 2. In order to suppress the film thickness at the edge of the wafer 2, plasma of nitrogen (N₂) gas is supplied before the step of supplying plasma of ammonia gas.

The substrate processing apparatus 10 includes a processing container 11 that accommodates the wafers 2 and forms a space therein where the wafers 2 are processed, a lid 20 that airtightly closes an opening at the lower end of the processing container 11, and a substrate holder 30 that holds the wafers 2. Each wafer 2 is, for example, a semiconductor substrate, more particularly, for example, a silicon wafer. The substrate holder 30 is also called a wafer boat.

The processing container 11 includes a ceilinged cylindrical processing container main body 12 with an opening at the lower end thereof. The processing container main body 12 is made of, for example, quartz. A flange unit 13 is formed at the lower end of the processing container main body 12. The processing container 11 further includes a manifold 14 having, for example, a cylindrical shape. The manifold 14 is made of, for example, a stainless steel. A flange unit 15 is formed at the upper end of the manifold 14, and the flange unit 13 of the processing container main body 12 is provided on the flange unit 15. A seal member 16 such as an O-ring is disposed between the flange unit 13 and the flange unit 15.

The lid 20 is airtightly attached to the opening at the lower end of the manifold 14 via a seal member 21 such as an O-ring. The lid 20 is made of, for example, a stainless steel. A through hole is formed at the center of the lid 20 to penetrate the lid 20 in the vertical direction. A rotary shaft 24 is disposed in the through hole. A magnetic fluid seal unit 23 seals the gap between the lid 20 and the rotary shaft 24. The lower end of the rotary shaft 24 is rotatably supported by an arm 26 of a lifting unit 25. A rotation plate 27 is provided on the upper end of the rotary shaft 24. The substrate holder 30 is provided on the rotation plate 27 via a heat insulating base 28.

The substrate holder 30 holds the plurality of wafers 2 to be vertically spaced apart from each other. Each of the plurality of wafers 2 is horizontally held. The substrate holder 30 is made of, for example, quartz (SiO₂) or silicon carbide (SiC). When the lifting unit 25 is moved up, the lid 20 and the substrate holder 30 move up, and the substrate holder 30 is carried into the processing container 11, so that the opening at the lower end of the processing container 11 is sealed by the lid 20. When the lifting unit 25 is moved down, the lid 20 and the substrate holder 30 move down, and the substrate holder 30 is carried out from the processing container 11. When the rotary shaft 24 is rotated, the substrate holder 30 rotates together with the rotation plate 27.

The substrate processing apparatus 10 includes three gas supply pipes 40A, 40B, and 40C. The gas supply pipes 40A, 40B, and 40C are made of, for example, quartz (SiO₂). The gas supply pipes 40A, 40B, and 40C supply a gas into the processing container 11. The type of gas is described herein below. One gas supply pipe may eject one type of gas or various types of gas in sequence. Further, a plurality of gas supply pipes may eject the same type of gas.

The gas supply pipes 40A, 40B, and 40C include horizontal pipes 43A, 43B, and 43C that horizontally penetrate the manifold 14, and vertical pipes 41A, 41B, and 41C that are arranged vertically inside the processing container 11. The vertical pipes 41A, 41B, and 41C include a plurality of gas supply ports 42A, 42B, and 42C arranged at intervals in the vertical direction. A gas supplied to the horizontal pipes 43A, 43B, and 43C is sent to the vertical pipes 41A, 41B, and 41C, and ejected horizontally from the plurality of gas supply ports 42A, 42B, and 42C. The vertical pipe 41C is disposed inside a plasma box 19. The vertical pipes 41A and 41B are disposed inside the processing container 11.

The substrate processing apparatus 10 includes an exhaust pipe 45. The exhaust pipe 45 is connected to an exhaust device (not illustrated). The exhaust device includes a vacuum pump to exhaust the inside of the processing container 11. An exhaust port 18 is formed in the processing container main body 12. The exhaust port 18 is disposed to face the gas supply ports 42A, 42B, and 42C. The gas horizontally ejected from the gas supply ports 42A, 42B, and 42C passes through the exhaust port 18, and then, is exhausted from the exhaust pipe 45. The exhaust device sucks the gas inside the processing container 11, and sends the gas to a detoxifying apparatus. The detoxifying apparatus removes harmful components from the exhausted gas, and then, discharges the exhausted gas into the atmosphere.

The substrate processing apparatus 10 further includes a heating unit 60. The heating unit 60 is disposed outside the processing container 11, and heats the inside of the processing container 11 from the outside of the processing container 11. For example, the heating unit 60 is formed in a cylindrical shape to surround the processing container main body 12. The heating unit 60 is configured with, for example, an electric heater. The heating unit 60 heats the inside of the processing container 11, thereby improving the processing capability of a gas supplied into the processing container 11.

### Plasma Box

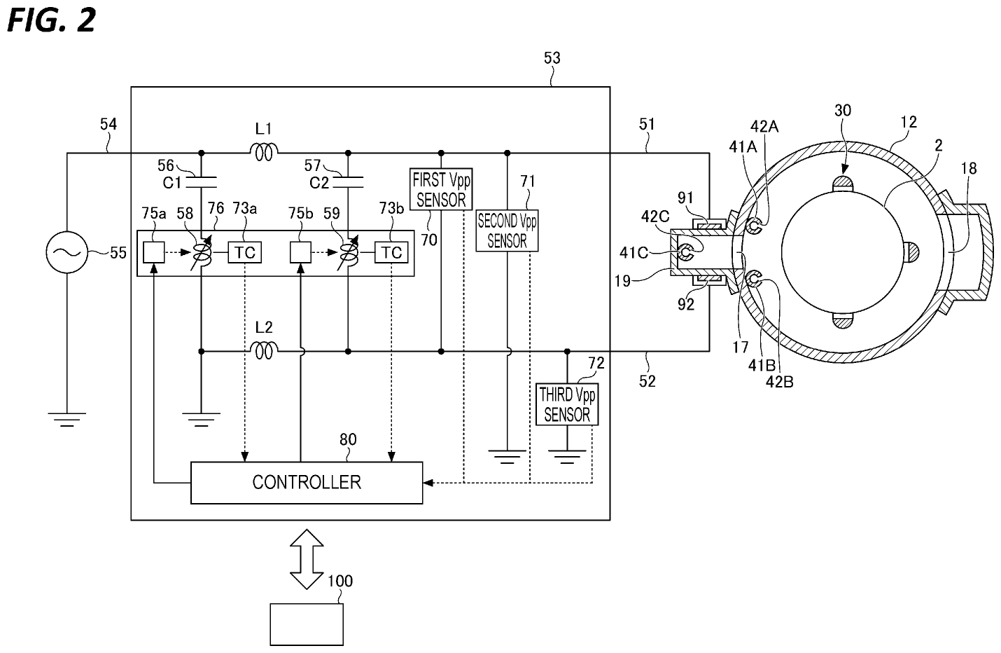

FIG. 2 is a view illustrating an example of a configuration of an impedance matching device 53 and the plasma box 19 according to an embodiment. As illustrated in FIGS. 1 and 2, an opening 17 is formed in a portion of the processing container main body 12 in the circumferential direction. The plasma box 19 is formed in the side surface of the processing container 11 to surround the opening 17. The plasma box 19 is formed to protrude radially outward from the processing container main body 12, and formed, for example, in a U shape when viewed in the vertical direction.

A pair of electrodes (electrode pair) 91 and 92 is arranged to sandwich the plasma box 19 therebetween. The electrodes 91 and 92 are a pair of parallel electrodes provided facing each other on the external side of the plasma box 19. The electrodes 91 and 92 are formed to be vertically elongated, similar to the vertical pipe 41C, while facing each other. An RF power supply 55 is connected to the electrodes 91 and 92 via the impedance matching device 53, and applies a radio-frequency voltage with a predetermined frequency to the electrodes 91 and 92.

The impedance matching device 53 is connected in series between the RF power supply 55 and the electrodes 91 and 92 via voltage supply lines 51 52, and 54. The impedance matching device 53 includes a first variable reactor 58, a second variable reactor 59, electronic circuits 75a and 75b, capacitors 56 (C1) and 57 (C2), and coils L1 and L2. The electronic circuit 75a controls the current flowing in the first variable reactor 58, to change the inductance of the first variable reactor 58. The electronic circuit 75b controls the current flowing in the second variable reactor 59, to change the inductance of the second variable reactor 59.

When the radio-frequency power is supplied from the RF power supply 55 to a load side (e.g., the side of the plasma box 19), the impedance matching device 53 matches the impedances between the RF power supply 55 and the load to improve the efficiency of supplying the radio-frequency power.

The stability of plasma ignition is enhanced as plasma reacts quickly and converges in short time until being stabilized after being excited. Further, the stability of plasma ignition is implemented by stabilizing the radio-frequency power supplied to plasma to suppress the fluctuation of plasma. To this end, it is necessary to perform the impedance matching at high speed, thereby suppressing the reflected wave.

In the ignition control method according to the present embodiment, the impedance matching is performed in the manner that the electronic circuits 75a and 75b control the currents flowing in the first variable reactor 58 and the second variable reactor 59 provided in the impedance matching device 53 to change the inductances of the variable reactors. The speed of change in inductances of the first variable reactor 58 and the second variable reactor 59 varies according to the operation speed of the electronic circuits 75a and 75b, and the time required to match the impedances is on the order of us (microseconds). Thus, the impedance matching device 53 including the first variable reactor 58 and the second variable reactor 59 may perform the impedance matching at high speed in short time (e.g., within 1 second) immediately before the plasma ignition.

The impedance matching device 53 includes a first Vpp sensor 70 that detects the voltage between the electrodes 91 and 92, a second Vpp sensor 71 that detects the voltage between the electrode 91 and the ground, and a third Vpp sensor 72 that detects the voltage between the electrode 92 and the ground. Further, the impedance matching device 53 includes a temperature sensor (TC) 73a that detects the temperature of the first variable reactor 58, and a temperature sensor (TC) 73b that detects the temperature of the second variable reactor 58.

Further, the impedance matching device 53 includes a controller 80. The controller 80 acquires detection values of the first Vpp sensor 70, the second Vpp sensor 71, and the third Vpp sensor 72, and detection values of the temperature sensors 73a and 73b. The controller 80 acquires the inter-electrode voltage from the first Vpp sensor 70 and the temperature of the first variable reactor 58 from the temperature sensor 73a, and controls the current flowing in the electronic circuit 75a based on the information. As a result, the inductance of the first variable reactor 58 is changed. Further, the controller 80 acquires the inter-electrode voltage from the first Vpp sensor 70 and the temperature of the second variable reactor 59 from the temperature sensor 73b, and controls the current flowing in the electronic circuit 75b based on the information. As a result, the inductance of the second variable reactor 59 is changed. In this way, the controller 80 may control the impedance matching at high speed without the control unit 100.

The controller 80 may control the impedance matching in cooperation with the control unit 100 that controls the entire substrate processing apparatus 10. The controller 80 and the control unit 100 are configured with, for example, computers.

### Overview of Operations of Variable Reactors

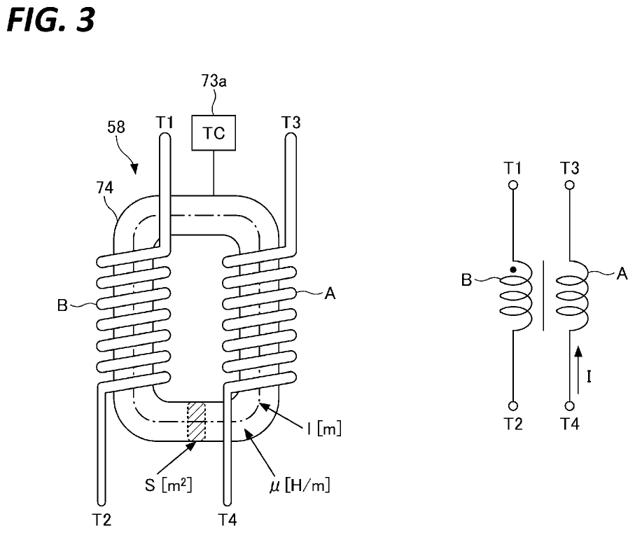

Referring to FIG. 3, an overview of the operations of the first variable reactor 58 and the second variable reactor 59 in the impedance matching device 53 is described. Since the second variable reactor 59 has the same configuration as the first variable reactor 58, the first variable reactor 58 is described below.

The first variable reactor 58 has a configuration in which a control wind A between T3 and T4 and an AC wind B between T1 and T2 are wound around a circular magnetic core 74. The electronic circuit 75a is connected between T3 and T4 (see, e.g., FIG. 2). The DC current I flowing in the control wind A is controlled to be variable, by the electronic circuit 75a. As a result, the inductance changes.

In the first variable reactor 58, when the temperature of the magnetic core 74 increases due to the environmental temperature, the magnetic permeability “μ” increases, and the inductance increases. When the temperature of the magnetic core 74 decreases, the magnetic permeability “μ” decreases, and the inductance decreases. Thus, in the case where the temperature change occurs in the first variable reactor 58, when the same current flows in the control wind A before and after the temperature change, the preset value deviates so that the reflected wave changes at the time of plasma ignition, which may affect the film formation according to processes. In particular, it has been found out through experiments that since the variable reactor is easily affected by the temperature change while the variable capacitor is hardly affected by the temperature change, the preset value easily changes.

The magnetic permeability “μ” [H/m] is a numerical value indicating the ease of magnetization of the magnetic core 74, and the relationship between the magnetic field intensity H and the magnetic flux density B is expressed by B=μH. The inductance L is expressed by Equation (1) using the cross-sectional area S [m²] of the magnetic core 74 illustrated in FIG. 3, the number of times of winding N of the control wind A and the AC wind B, and the length 1 [m] that passes through the center of the magnetic core 74. Thus, as the magnetic permeability “μ” increases, the inductance L increases.

1=μSN²/1 [H] (1)

Immediately before applying the radio-frequency voltage from the RF power supply 55 to the electrodes 91 and 92, the adjustment positions of the first variable reactor 58 and the second variable reactor 59 of the impedance matching device 53 are set to preset values. Thus, while controlling the reflected wave, the stable plasma ignition is performed.

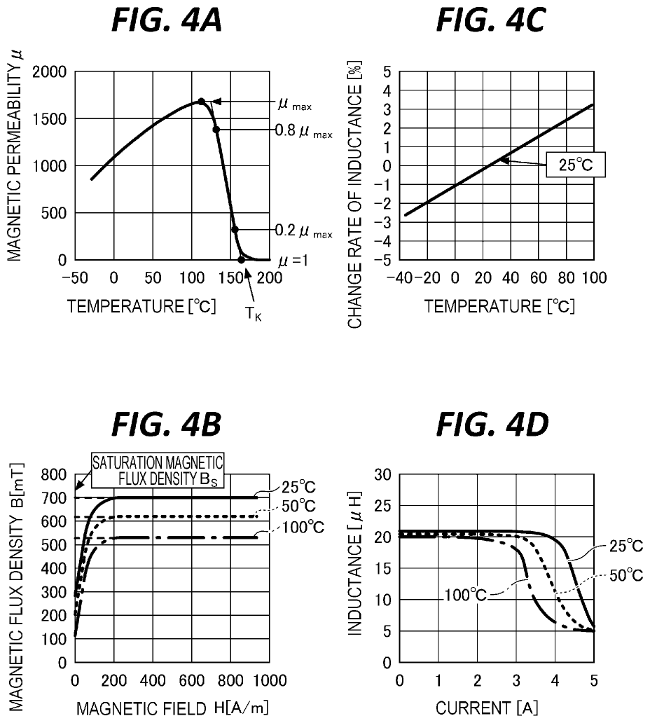

However, as described above, the inductances of the first variable reactor 58 and the second variable reactor 59 may change due to the temperature change in the reactors, which may deteriorate the accuracy of the preset values. The temperature change of the variable reactors and the problem arising at the time of plasma ignition are further described with reference to FIGS. 4A to 4D. FIGS. 4A to 4D are views for describing the temperature change of the variable reactors and the problem arising at the time of plasma ignition.

In the graph of FIG. 4A, the horizontal axis represents the temperature of the variable reactor, and the vertical axis represents the magnetic permeability “μ.” According to the graph, as the temperature of the variable reactor increases, the magnetic permeability “μ” increases. From Equation (1), it may be understood that since the inductance of the variable reactor increases as the magnetic permeability “μ” increases, the inductance of the variable reactor increases as the temperature of the variable reactor increases. However, when the temperature of the variable reactor becomes close to, or equal to or more than the Curie temperature T_{K} in FIG. 4A, the proportional relationship in which the magnetic permeability “μ” increases with the increase of the temperature falls apart. Thus, the temperatures of the first variable reactor 58 and the second variable reactor 59 may be controlled to 100° C. or lower.

In the present embodiment, the DC current I flowing in the control wind A (see, e.g., FIG. 3) is controlled to be variable according to the temperatures detected by the temperature sensors 73a and 73b attached to the first variable reactor 58 and the second variable reactor 59, respectively. Thus, the magnetic permeability “μ” in the magnetic core 74 is made variable, and the inductance of each of the first variable reactor 58 and the second variable reactor 59 is changed. As a result, the preset values are suppressed from changing due to the temperature change of the variable reactors.

In order to control the temperatures of the first variable reactor 58 and the second variable reactor 59 to 100° C. or lower, the impedance matching device 53 includes a temperature adjustment unit that adjusts the temperatures of the first variable reactor 58 and the second variable reactor 59. As illustrated in FIG. 2, a thermostatic bath 76 is provided as an example of the temperature adjustment unit to surround the first variable reactor 58 and the second variable reactor 59 and be capable of adjusting the temperature of each variable reactor. The thermostatic bath 76 controls the temperatures of the first variable reactor 58 and the second variable reactor 59 to 100° C. or lower. However, the temperatures of the first variable reactor 58 and the second variable reactor 59 change to some extent even due to the thermostatic bath 76. The thermostatic bath 76 may enclose the entire impedance matching device 53.

As another example of the temperature adjustment unit, a fan may be attached in the vicinity of the first variable reactor 58 and the second variable reactor 59. Further, as another example of the temperature adjustment unit, a piping structure may be formed near the first variable reactor 58 and the second variable reactor 59 to allow the flow of a temperature adjustment medium therein, and the temperatures of the first variable reactor 58 and the second variable reactor 59 may be adjusted by controlling the temperature of the temperature adjustment medium.

In the graph of FIG. 4B, the horizontal axis represents the magnetic field intensity H, and the vertical axis represents the magnetic flux density B. As described above, the magnetic permeability “μ” is expressed by B=μH. FIG. 4B represents cases where the temperature of the variable reactor is 25° C., 50° C., and 100° C. As the temperature of the variable reactor increases, the saturation magnetic flux density B_{S} decreases. Thus, in order to avoid reaching the saturation magnetic flux density B_{S} if possible, the temperature of the variable reactor may be controlled to a temperature lower than 100° C.

In the graph of FIG. 4C, the horizontal axis represents the temperature of the variable reactor, and the vertical axis represents the change rate of the inductance. When the temperature of the variable reactor increases, the change rate of the inductance increases even though the same current flows in the variable reactor. Thus, when the temperature of the variable reactor increases, the deviation of the preset value increases. Therefore, it is better to lower the temperature of the variable reactor, thereby decreasing the change rate of the inductance.

In the graph of FIG. 4D, the horizontal axis represents the DC current flowing in the control wind A (see, e.g., FIG. 3), and the vertical axis represents the inductance. FIG. 4D represents cases where the temperature of the variable reactor is 25° C., 50° C., and 100° C. As the temperature of the variable reactor increases, the width of the current value in which the inductance is constant with respect to the DC current flowing in the control wind A becomes narrow, so that the rate in which the inductance changes with respect to the DC current flowing in the control wind A increases, and the deviation of the preset value increases.

As described above, the inductance changes due to the temperature change of the variable reactor caused by the ambient environment or the operation status of the apparatus, and the change rate of the inductance increases as the temperature rise of the variable reactor is significant. Accordingly, the preset value before the supply of the radio-frequency power from the RF power supply 55 changes, and the reflected wave at the time of plasma ignition immediately after the supply of the radio-frequency power changes. As a result, the state of film formation is adversely affected. Thus, in the ignition control method according to the present embodiment, the inductance is changed by controlling the current flowing in the control wind A according to the temperature change of the variable reactor, and as a result, the accuracy of the preset value of the variable reactor is improved. In this way, the preset value with the high accuracy may be set, so that the reflected wave or the inter-electrode voltage at the time of plasma ignition may be stably controlled, and the substrate processing apparatus 10 capable of stably controlling the film formation may be provided.

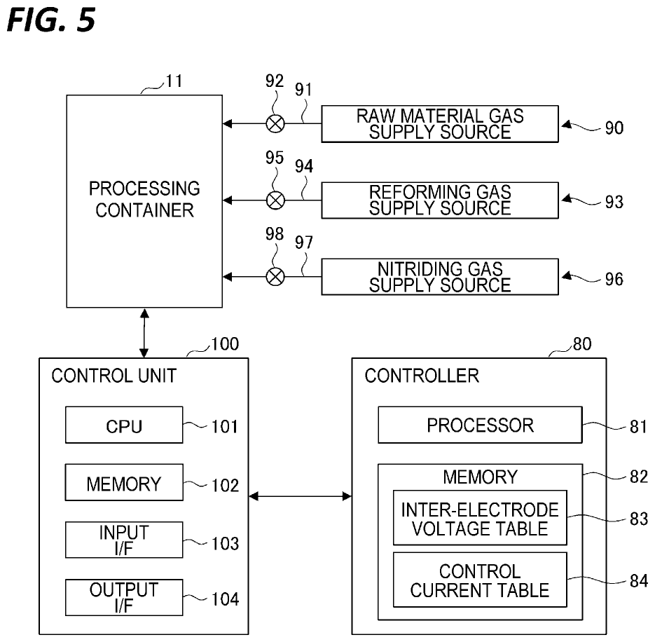

Next, the gas supply source, the control unit 100, and the controller 80 are described with reference to FIG. 5. FIG. 5 is a view illustrating the gas supply source, the control unit 100, and the controller 80 of the substrate processing apparatus 10 according to an embodiment.

In the substrate processing apparatus 10, the gas supply unit includes a raw material gas supply source 90, a reforming gas supply source 93, and a nitriding gas supply source 96. The raw material gas supply source 90 supplies a raw material gas into the processing container 11. The raw material gas contains an element to be nitridated (e.g., silicon).

For example, dichlorosilane (DCS: SiH₂Cl₂) gas is used as the raw material gas. While the raw material gas of the present embodiment is DCS gas, the technology of the present disclosure is not limited thereto.

A raw material gas pipe 91 connects the raw material gas supply source 90 to the gas supply pipes 40A and 40B, to feed the raw material gas from the raw material gas supply source 90 to the gas supply pipes 40A and 40B. The raw material gas is ejected horizontally toward the wafers 2 from the gas supply ports 42A and 42B of the vertical pipes 41A and 41B. A raw material gas flow control valve 92 is provided in the middle of the raw material gas pipe 91 to control the flow rate of the raw material gas.

The reforming gas supply source 93 supplies a reforming gas into the processing container 11 to reform a Si-containing layer. The reformation of the Si-containing layer includes, for example, removing halogen elements included in the Si-containing layer. The reforming gas may be nitrogen gas, hydrogen gas, ammonia gas, or a gas containing any of these gases.

A reforming gas pipe 94 connects the reforming gas supply source 93 to the gas supply pipe 40C, to feed the reforming gas from the reforming gas supply source 93 to the gas supply pipe 40C. The reforming gas is ejected horizontally toward the wafers 2 from the gas supply port 42C of the vertical pipe 41C. A reforming gas flow control valve 95 is provided in the middle of the reforming gas pipe 94 to control the flow rate of the reforming gas.

The nitriding gas supply source 96 supplies a nitriding gas into the processing container 11 to nitride the Si-containing layer. The nitriding gas is, for example, ammonia (NH₃) gas, organic hydrazine compound gas, amine-based gas, NO gas, N₂O gas, or NO₂ gas.

A nitriding gas pipe 97 connects the nitriding gas supply source 96 to the gas supply pipe 40C, to feed the nitriding gas from the nitriding gas supply source 96 to the gas supply pipe 40C. The nitriding gas is ejected horizontally toward the wafers 2 from the gas supply port 42C of the vertical pipe 41C. A nitriding gas flow control valve 98 is provided in the middle of the nitriding gas pipe 97 to control the flow rate of the nitriding gas.

A purge gas supply source (not illustrated) may be provided. By supplying a pure gas into the processing container 11, the raw material gas, the reforming gas, and the nitriding gas remaining inside the processing container 11 are removed. For example, an inert gas is used as the purge gas. A noble gas such as Ar gas, or N₂ gas is used as the inert gas.

As illustrated in FIG. 5, the substrate processing apparatus 10 includes the control unit 100 that controls the substrate processing apparatus 10. The control unit 100 includes a central processing unit (CPU) 101, a memory 102, an input interface 103, and an output interface 104. The memory 102 stores programs that control various processes performed in the substrate processing apparatus 10. The control unit 100 controls the overall operation of the substrate processing apparatus 10 by causing the CPU 101 to execute the programs stored in the memory 102. The control unit 100 receives signals from the outside through the input interface 103, and transmits signals to the outside through the output interface 104.

The programs may be stored in a computer readable medium, and installed from the medium into the memory 102 of the control unit 100. Examples of the computer readable medium include a hard disk (HD), a flexible disk (FD), a compact disk (CD), a magnet optical disk (MO), and a memory card. Further, the programs may be downloaded from a server through the Internet, and installed in the memory 102 of the control unit 100.

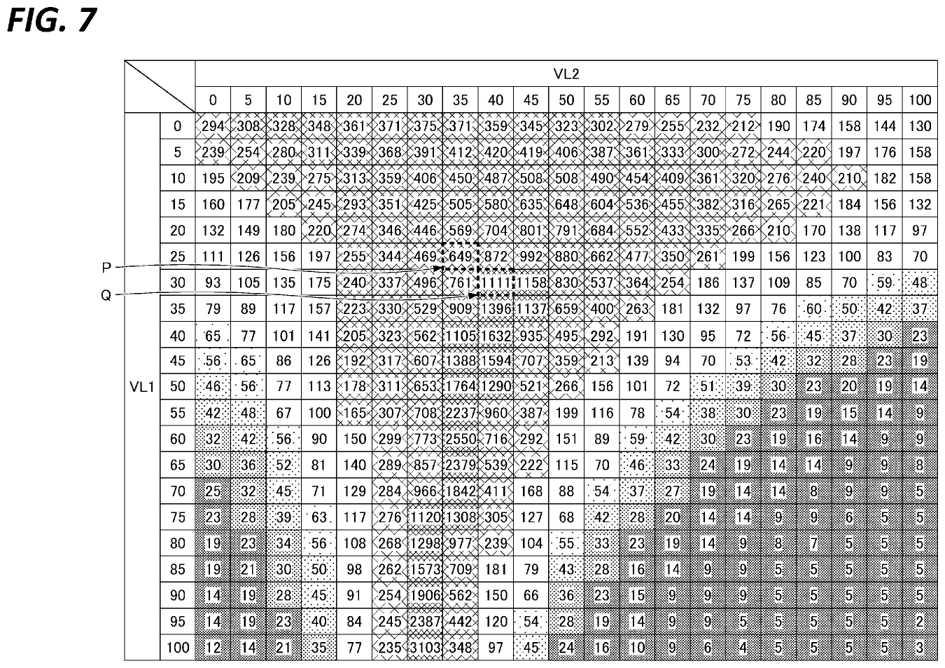

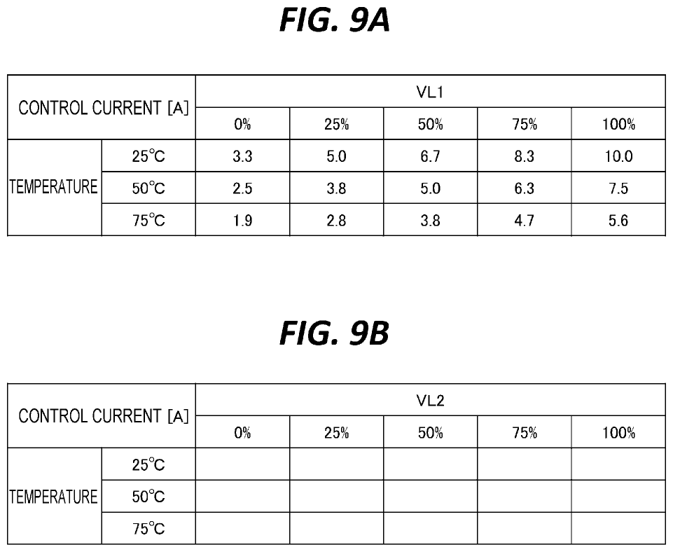

The controller 80 includes a processor 81 and a memory 82. The memory 82 stores an ignition control program, an inter-electrode voltage table 83 (see, e.g., FIG. 7), and a control current table 84 (see, e.g., FIG. 9). The controller 80 causes the processor 81 to execute the ignition control program, using the various tables stored in the memory 102, to control the operation of the impedance matching device 53, which includes the current control of the electronic circuits 75a and 75b.

The ignition control program may be stored in a computer readable medium by the processor 81, and installed from the medium into the memory 82 of the controller 80.

### Ignition Control Method

In the ignition control method according to the present embodiment, the current in each variable reactor is controlled based on the temperature change of the first variable reactor 58 and the second variable reactor 59, so that the preset value with the high accuracy is set, and the stable plasma ignition is performed. As a result, the control performance of the thickness and quality of the film on the wafers 2 may be improved, and the film with the satisfactory quality may be formed.

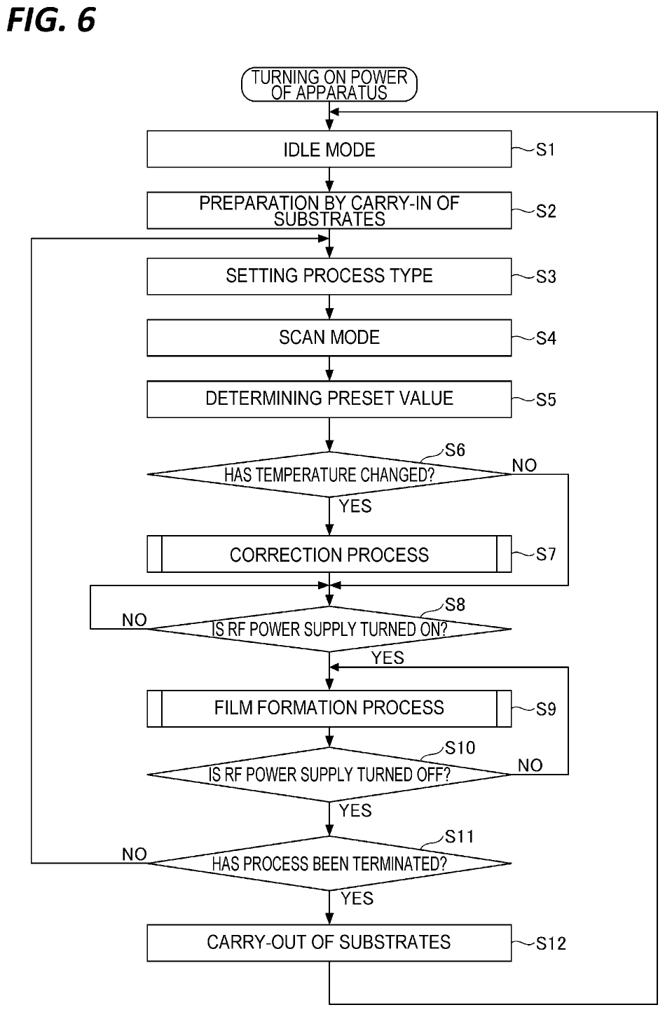

The ignition control method according to the present embodiment is described with reference to FIGS. 6 and 7. FIG. 6 is a flowchart illustrating the ignition control method according to an embodiment. FIG. 7 is an example of an inter-electrode voltage table at each adjustment position of the variable reactor. The ignition control method according to an embodiment is controlled by the controller 80 or the control unit 100. In the present example, when the RF power supply 55 is turned ON, a radio-frequency voltage with a predetermined frequency (e.g., 13.56 MHz) is applied. FIG. 7 represents an example of an inter-electrode voltage table at each adjustment position VL1, VL 2 of the inductance of each variable reactor, for example, when RF of 13.56 MHz is applied.

In FIG. 6, when the power of the substrate processing apparatus 10 is turned ON, an idle mode is executed in step S1. During the idle mode, the radio-frequency voltage from the RF power supply 55 is turned OFF. In this state, the control unit 100 supplies nitrogen gas from the plurality of gas supply ports 42A, 42B, and 42C of the vertical pipes 41A, 41B, and 41C.

In step S2, the control unit 100 carries the wafers 2 loaded on the substrate holder 30 into the processing container 11, and prepares for a film formation process. First, a transfer device loads the plurality of wafers 2 on the substrate holder 30 outside the processing container 11. The substrate holder 30 holds the plurality of wafers 2 horizontally at intervals in the vertical direction. Next, the lifting unit 25 is moved up to move up the lid 20 and the substrate holder 30. The wafers 2 are carried into the processing container 11 together with the substrate holder 30, and the opening at the lower end of the processing container 11 is sealed by the lid 20.

In step S3, the control unit 100 sets a process type of a process to be performed on the wafers 2. The process type is identification information specifying process conditions for a substrate, and is assigned for each of the frequency of the radio frequency output from the RF power supply 55, the type of gas supplied into the processing container 11, and the temperature and pressure in the processing container 11.

In step S4, the control unit 100 sets the temperatures of the first variable reactor 58 and the second variable reactor 59 to a first temperature (e.g., 25° C.). The RF power supply 55 supplies a low-power radio-frequency power with a frequency of, for example, 13.56 MHz, at which no plasma discharge (ignition) occurs (e.g., 100 W), and at this time, the control unit 100 acquires first information indicating an inter-electrode voltage for each of a plurality of adjustment positions of the first variable reactor 58 and the second variable reactor 59. The first Vpp sensor 70 measures (detects) the inter-electrode voltage for each of the plurality of adjustment positions of the first variable reactor 58 and the second variable reactor 59, and transmits the measured voltage to the controller 80. Thus, a scan mode is executed to measure the inter-electrode voltage of each adjustment position in a matrix representing the range of 0% to 100% of each adjustment position VL1, VL2 in 5% increments as illustrated in FIG. 7. That is, the controller 80 scans the range of 0% to 100% of each adjustment position VL1, VL2 in, for example, 5% increments, and generates a table of the first information as illustrated in FIG. 7, i.e., the inter-electrode voltage table 83. After the measurement, the output of the low power from the RF power supply 55 is stopped. The inter-electrode voltage table 83 is an example of the first information.

In step S5, based on the inter-electrode voltage table 83, the controller 80 determines the adjustment position VL1, VL2, at which an inter-electrode voltage that is not excessively high may be obtained as a voltage equal to or more than the discharge voltage according to the Paschen's law, to be a preset value. For example, it is assumed that the controller 80 determines the position where VL1 is 25% and VL2 is 35% in FIG. 7, to be a preset value P.

In step S6, the controller 80 acquires the temperatures of the first variable reactor 58 and the second variable reactor 59 that are detected by the temperature sensors 73a and 73b. Descriptions are continued defining the acquired temperatures as second temperatures. The controller 80 determines whether at least one of the second temperature of the first variable reactor 58 and the second temperature of the second variable reactor 59 has changed from the first temperature. The first temperature is the temperature of the first variable reactor 58 and the second variable reactor 59 when the inter-electrode voltage table 83 is generated.

When it is determined in step S6 that at least one of the second temperature of the first variable reactor 58 and the second temperature of the second variable reactor 59 has changed from the first temperature, the process proceeds to step S7, and the controller 80 performs the correction process.

For example, as to the preset value P of FIG. 7, since the inductance of each variable reactor changes due to the temperature change of the first variable reactor 58 and the second variable reactor 59, an appropriate preset value deviates from the current preset value by about several %. Thus, the preset value P that has been set may not be an appropriate value due to the temperature change of the variable reactors. For example, even when the preset value P of FIG. 7 deviates by an 5% increment to the position Q where VL1 is 30% and VL2 is 40%, the inter-electrode voltage is substantially doubled from 649 V to 1,111 V. That is, the plasma ignition occurs at the position where the inter-electrode voltage is 1,111 V, and not 649 V. As a result, the thickness and quality of the film on the wafers 2 are deteriorated.

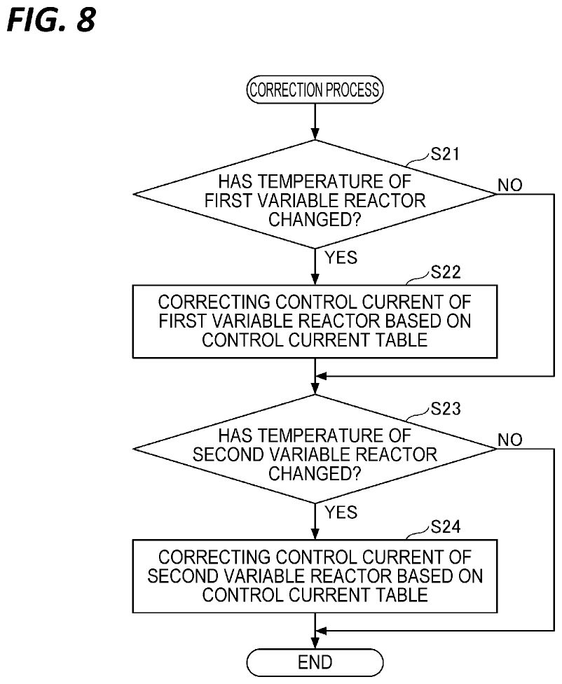

Thus, in the correction process of step S7, the controller 80 controls the electronic circuits 75a and 75b to change the current flowing in the first variable reactor 58 and the second variable reactor 59 according to the second temperatures detected by the temperature sensors 73a and 73b. As a result, the inductance is changed, so that the preset value with the high accuracy may be set. In this way, the radio-frequency voltage indicated by the determined preset value is applied to the electrodes 91 and 92, even though the temperatures of the variable reactors change. Therefore, the reflected wave and the inter-electrode voltage may be stably controlled, so that plasma may be stably ignited. Details of the correction process are described herein below with reference to FIGS. 8, 9A, and 9B.

In step S8, the control unit 100 determines whether the radio-frequency power enabling the plasma ignition has been supplied from the RF power supply 55. For example, when a radio-frequency power set in a process recipe is supplied, the control unit 100 determines that the radio-frequency power enabling the plasma ignition has been supplied from the RF power supply 55, and proceeds with step S9.

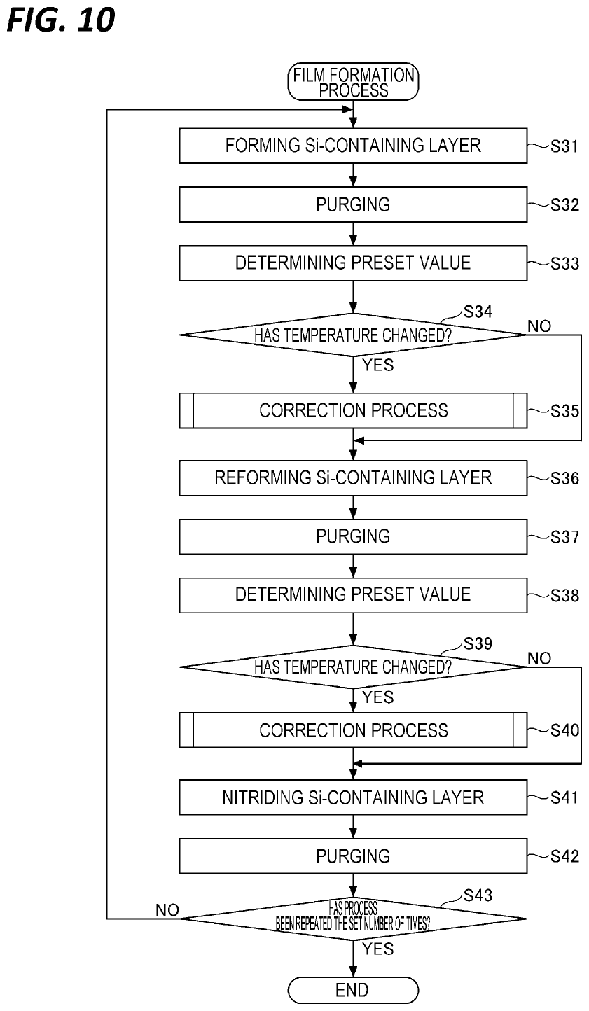

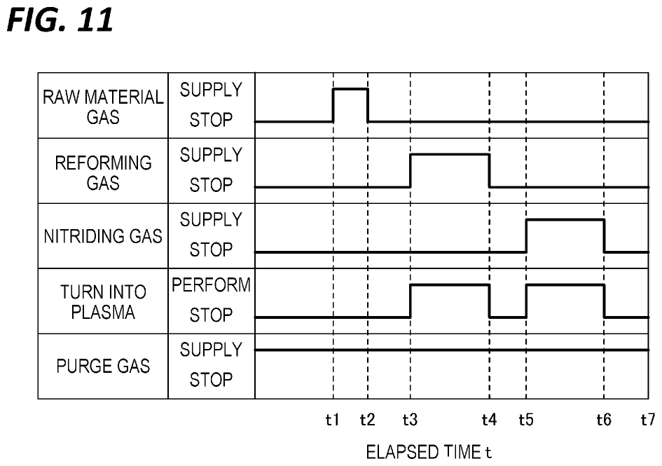

In step S9, the control unit 100 executes the film formation process corresponding to the process type set for the wafers 2. The film formation process is described herein below with reference to FIGS. 10 and 11.

In step S10, the control unit 100 determines whether the RF power supply 55 has been turned OFF. When it is determined that the RF power supply 55 has been turned OFF, the control unit 100 proceeds with step S11 to determine whether the process has been terminated.

In step S11, when it is determined that the process has not been terminated, the control unit 100 returns to step S3 to execute the subsequent process. When it is determined in step S11 that the process has been terminated, the control unit 100 proceeds with step S12 to carry out the substrate.

Then, the process returns to step S1 to wait until the next wafers 2 are carried into the processing container 11 (idle mode). When the next wafers 2 are carried into the processing container 11, the same process as described above is performed on the next wafers 2.

### Correction Process

The correction process according to an embodiment is described with reference to FIGS. 8, 9A, and 9B. FIG. 8 is a flowchart illustrating an example of the correction process performed in step S7 of FIG. 6. FIGS. 9A and 9B are an example of a control current table for a variable reactor according to an embodiment. The correction process of FIG. 8 is controlled by the controller 80.

In step S21, the controller 80 determines whether the second temperature of the first variable reactor 58 (the temperature of the first variable reactor 58 detected by the temperature sensor 93a immediately before the RF power supply 55 is turned ON) has changed from the first temperature.

When it is determined in step S21 that the second temperature is the same as the first temperature, the controller 80 proceeds with step S23. When it is determined in step S21 that the second temperature is different from the first temperature, the controller 80 proceeds with step S22 to determine the control current according to the second temperature by referring to the control current table 84, and change the control current of the first variable reactor 58 using the electronic circuit 75a.

In the control current table 84, the control currents of the electronic circuits 75a and 75b according to the temperatures of the respective variable reactors are set for VL1 (%) of the first variable reactor 58 and VL2 (%) of the second variable reactor 59.

For example, at the preset value P of FIG. 7, VL1 is 25%. When the second temperature is 50° C., the first temperature is 25° C. Thus, the controller 80 changes the current flowing in the first variable reactor 58 from 5.0 A to 3.8 A by referring to the control current table 84 represented in FIG. 9A.

In step S23, the controller 80 determines whether the second temperature of the second variable reactor 59 (the temperature of the second variable reactor 59 detected by the temperature sensor 93b immediately before the RF power supply 55 is turned ON) has changed from the first temperature.

When it is determined in step S23 that the second temperature is the same as the first temperature, the controller 80 terminates the process. When it is determined in step S23 that the second temperature is different from the first temperature, the controller 80 proceeds with step S24, determines the control current according to the second temperature by referring to the control current table 84 represented in FIG. 9B, changes the control current of the second variable reactor 59 using the electronic circuit 75b, and terminates the process.

For example, at the preset value P of FIG. 7, VL2 is 30%. The controller 80 changes the current flowing in the second variable reactor 59 by referring to the control current table 84 represented in FIG. 9B.

### Film Formation Process

The film formation process according to an embodiment is described with reference to FIGS. 10 and 11. FIG. 10 is a flowchart illustrating an example of the film formation process performed in step S9 of FIG. 6. FIG. 11 is a time chart illustrating an example of the film formation process of FIG. 10. The film formation process of FIG. 10 is mainly controlled by the control unit 100, and the correction process before the plasma ignition is controlled by the controller 80. In FIG. 10, the film formation process for silicon nitride film (SiN) is performed by the ALD method.

In step S31, the control unit 100 forms a Si-containing layer on the wafers 2 held in the substrate holder 30. Step S31 is performed from time t1 to time t2 represented in FIG. 11. In step S31, the raw material gas is supplied into the processing container 11 from the raw material gas supply source 90 while exhausting the inside of the processing container 11 by the exhaust device connected to the exhaust pipe 45. The raw material gas is, for example, DCS gas. As a result, a Si-containing layer is formed on the wafers 2. The time for performing step S31 is, for example, 1 second to 10 seconds.

In step S32, the control unit 100 performs a purging process. Step S32 is performed from time t2 to time t3 represented in FIG. 11. In step S32, while exhausting the inside of the processing container 11 by the exhaust device, the supply of the raw material gas is stopped, and a purge gas is supplied into the processing container 11. As a result, the gas remaining inside the processing container 11 is replaced with the purge gas. The purge gas may be nitrogen gas, argon gas, other inert gas, or a combination thereof. The time for performing step S32 is, for example, 3 seconds to 10 seconds. The purge gas may be supplied from, for example, the nitriding gas supply source 96. As illustrated in FIG. 11, the purge gas may be supplied continuously in all steps.

In steps S33 to S35, the controller 80 determines the preset value as in steps S5 to S7 of FIG. 6 (step S33: the same process as step S5), determines whether the temperature of each variable reactor has changed (step S34: the same process as step S6), and performs the correction process when the temperature has changed (step S35: the same process as step S7).

In step S36, the control unit 100 reforms the Si-containing layer. Step S36 is performed from time t3 to time t4 represented in FIG. 11. In step S36, the reforming gas is supplied into the processing container 11 by the reforming gas supply source 93, while exhausting the inside of the processing container 11 by the exhaust device. In step S36, the radio-frequency power is supplied from the RF power supply 55 to cause the plasma ignition in the plasma box 19, thereby turning the reforming gas into plasma. The frequency of the radio-frequency of the RF power supply 55 is, for example, 13.56 MHz.

The reforming gas is, for example, nitrogen gas. The reforming gas may be hydrogen gas or ammonia gas. The reforming gas may be a gas including nitrogen gas or a gas including hydrogen gas. The reforming gas that has been turned into plasma reforms the Si-containing layer. The time for performing step S36 is, for example, from 3 seconds to 60 seconds.

In step S37, the control unit 100 performs purging. Step S37 is performed from time t4 to time t5 represented in FIG. 11. In step S24, while exhausting the inside of the processing container 11 by the exhaust device, the supply of the reforming gas and the radio-frequency power is stopped, and the purge gas is supplied into the processing container 11. As a result, the gas remaining inside the processing container 11 is replaced with the purge gas. The time for performing step S37 is, for example, from 3 seconds to 10 seconds. The purge gas may be, for example, nitrogen gas, and may be supplied from, for example, the nitriding gas supply source 96.

In steps S38 to S40, the controller 80 determines the preset value (step S38) as in steps S5 to S7 of FIG. 6, determines whether the temperature of each variable reactor has changed (step S39), and performs the correction process (step S40) when the temperature has changed.

In step S41, the control unit 100 nitrides the Si-containing layer. Step $41 is performed from time t5 to time t6 represented in FIG. 11. In step S41, the nitriding gas is supplied into the processing container 11 by the nitriding gas supply source 96, while exhausting the inside of the processing container 11 by the exhaust device. In step S41, the radio-frequency power is supplied from the RF power supply 55 to cause the plasma ignition in the plasma box 19, thereby turning the nitriding gas into plasma.

The nitriding gas is, for example, ammonia gas. The ammonia gas that has been turned into plasma nitrides the Si-containing layer. The time for performing step S41 is, for example, from 5 seconds to 120 seconds.

In step S42, the control unit 100 performs purging. Step S42 is performed from time t6 to time t7 represented in FIG. 11. In step S42, while exhausting the inside of the processing container 11 by the exhaust device, the supply of the nitriding gas and the radio-frequency power is stopped, and the purge gas is supplied into the processing container 11. As a result, the gas remaining inside the processing container 11 is replaced with the purge gas. The time for performing step S42 is, for example, from 3 seconds to 10 seconds. The purge gas may be, for example, nitrogen gas, and may be supplied from the nitriding gas supply source 96.

In step S43, the control unit 100 determines whether the process has been repeated the set number of times. The set number of times is set in advance. When it is determined that the process has not been repeated the set number of times, the control unit 100 returns to step S31, and repeats steps S31 to S43 as one cycle the predetermined number of times. In step S43, when it is determined that the process has been repeated the set number of times, the control unit 100 terminates the current process since the silicon nitride film with the desired film thickness and quality has been formed. In the film formation method, the purging step may be omitted.

In the ignition control method described above, the correction process of FIG. 8 is performed as represented in steps S5 to S7 of FIG. 6, and steps S33 to S35 and S38 to S40 of FIG. 10, to change the control current of the electronic circuit controlling each variable reactor according to the temperatures of the first variable reactor 58 and the second variable reactor 59. As a result, the inductance of each variable reactor may be changed, and therefore, may be controlled to be constant even when the temperature of each variable reactor changes, so that the accuracy of the preset value may be improved.

In particular, when the step of performing the plasma ignition is repeated according to the repetition of ON/OFF of the gas during the film formation process using the ALD method, the preset value changes at each timing when ON/OFF of the gas are repeated. For example, in the ignition control method according to the present embodiment, the preset value may be corrected in real time at the timing immediately before the plasma ignition is performed by supplying the radio-frequency power, as represented in steps S33 to S35 and S38 to S40 of FIG. 10. As a result, it is possible to provide the substrate processing apparatus 10, which performs the stable film formation by improving the accuracy of the preset value, and thus, stably controlling the reflective wave and the inter-electrode voltage.

As described above, according to the ignition control method and the substrate processing apparatus of the present embodiment, the preset value with the high accuracy may be set, so that the reflected wave may be suppressed, and thus, the stable plasma ignition may be performed. As a result, the control performance of the film thickness and the film quality may be improved, and therefore, a satisfactory film may be formed.

The ignition control method, the film formation method, and the film formation apparatus according to the embodiment described above are examples in all aspects, and should not be construed as being limited.

For example, in the present embodiment, two variable reactors are used. However, the number of variable reactors provided in the impedance matching device 53 is not limited thereto, and may be one. When the impedance matching device 53 includes two reactors, one of the two variable reactors may be a variable reactor, and the other may be a fixed reactor. The ignition control method of the present disclosure may be performed by a single variable reactor, or one variable reactor of two reactors.

The ignition control method of the present disclosure may be used for all substrate processing apparatuses that generate plasma by applying the radio-frequency voltage between the electrodes via the impedance matching device including variable reactors. For example, the substrate processing apparatus that performs the ignition control method of the present disclosure are not limited to the ALD apparatus. The substrate processing apparatus of the present disclosure may be, for example, an atomic layer etching (ALE) apparatus, a chemical vapor deposition (CVD) apparatus, or a physical vapor deposition (PVD) apparatus.

The substrate processing apparatus of the present disclosure may be applied to any type of apparatus among capacitively coupled plasma (CCP), inductively coupled plasma (ICP), radial line slot antenna (RLSA), electron cyclotron resonance plasma (ECR), and helicon wave plasma (HWP).

The substrate processing apparatus of the present disclosure is not limited to the batch-type substrate processing apparatus. For example, the substrate processing apparatus may be a single-wafer type apparatus that processes wafers one by one. Further, the substrate processing apparatus may be a semi-batch type apparatus. The semi-batch type apparatus may be an apparatus in which a plurality of wafers arranged around a rotation central line of a rotary table is rotated together with the rotary table, and caused to pass through a plurality of regions where different gases are supplied.

The substrate processing performed by the substrate processing apparatus of the present disclosure includes, for example, a film formation process and an etching process. In particular, the substrate processing is suitable for the film formation by the ALD method and the etching by the ALE method.

The controller 80 may be disposed inside the impedance matching device 53 or outside the impedance matching device 53. When the controller 80 is disposed outside the impedance matching device 53, the control unit 100 and the controller 80 of FIG. 5 may be provided as separate components as illustrated in FIG. 5 or in an integrated form. Further, the ignition control method (FIG. 6), the correction process (FIG. 8), and the film formation process (FIG. 10) are not limited to those described above, and may be performed by either the control unit 100 or the controller 80.

According to an aspect, the accuracy of a preset value of a variable reactor may be improved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An ignition control method comprising:
(a) providing a substrate processing apparatus including
a processing container configured to accommodate a substrate,
a pair of electrodes disposed in the processing container,
a matching box including a variable reactor and an electronic circuit that controls a current flowing in the variable reactor,
an RF power supply connected to the pair of electrodes via the matching box, and
a temperature sensor configured to detect a temperature of the variable reactor;
(b) setting the temperature of the variable reactor to a first temperature, and measuring first information indicating a voltage between the pair of electrodes for each of a plurality of adjustment positions of the variable reactor when a radio-frequency voltage of a predetermined frequency is applied from the RF power supply to the pair of electrodes;
(c) determining a preset value of the variable reactor based on the first information measured in (b);
(d) acquiring the temperature of the variable reactor detected by the temperature sensor as a second temperature; and
(e) when the first temperature and the second temperature are different from each other, correcting the current flowing in the variable reactor by controlling the electronic circuit such that an adjustment position of the variable reactor at the second temperature becomes the preset value determined in (c).

2. The ignition control method according to claim 1, wherein (e) corrects the current flowing in the variable reactor when the temperature of the variable reactor is the second temperature, by referring to a memory that stores the current flowing in the variable reactor according to the plurality of adjustment positions of the variable reactor for each temperature of the variable reactor, thereby correcting the preset value determined in (c).

3. The ignition control method according to claim 1, wherein (c) measures the first information immediately before plasma ignition.

4. The ignition control method according to claim 1, wherein when measuring the first information, (c) supplies a radio-frequency power with an intensity that does not cause plasma ignition, from the RF power supply.

5. The ignition control method according to claim 1, wherein (e) corrects the current flowing in the variable reactor immediately before plasma ignition.

6. A substrate processing apparatus comprising:
a processing container configured to accommodate a substrate;
a pair of electrodes disposed in the processing container;
a matching box including a variable reactor and an electronic circuit that controls a current flowing in the variable reactor;
an RF power supply connected to the pair of electrodes via the matching box;
a temperature sensor configured to detect a temperature of the variable reactor;
a temperature adjuster configured to adjust at least the temperature of the variable reactor; and
a controller,
wherein the controller controls a process including
(a) setting the temperature of the variable reactor to a first temperature, and measuring first information indicating a voltage between the pair of electrodes for each of a plurality of adjustment positions of the variable reactor when a radio-frequency voltage of a predetermined frequency is applied from the RF power supply to the pair of electrodes;
(b) determining a preset value of the variable reactor based on the first information measured in (a);
(c) acquiring the temperature of the variable reactor detected by the temperature sensor as a second temperature; and
(d) when the first temperature and the second temperature are different, correcting the current flowing in the variable reactor by controlling the electronic circuit such that an adjustment position of the variable reactor at the second temperature becomes the preset value determined in (b).

7. The substrate processing apparatus according to claim 6, wherein the temperature adjuster is any one of a thermostatic bath that surrounds at least the variable reactor, a fan that adjusts at least the temperature of the variable reactor, and a piping structure in which a temperature adjustment medium for adjusting at least the temperature of the variable reactor flows.
